(19) United States
(12) Patent Application Publication
(10) Pub. No.: US 2006/0063334 A1
(43) Pub. Date: Mar. 23, 2006

(54) Fin FET diode structures and methods for building

(75) Inventors: Richard Lee Donze, Rochester, MN (US); Karl Robert Erickson, Rochester, MN (US); William Paul Hovis, Rochester, MN (US); John Edward Sheets II, Zumbrota, MN (US); Jon Robert Tetzloff, Rochester, MN (US); Laura Marie Zumbrunnen, Rochester, MN (US)

Correspondence Address: IBM CORPORATION;ROCHESTER IP LAW DEPT 917, 3605 HIGHWAY 52 N, ROCHESTER, MN, 55901-7829, US

(73) Assignee: International Business Machines Corporation, Armonk, NY (US)

(21) Appl. No.: 10/944,624

(22) Filed: Sep. 17, 2004

(51) Int. Cl. H01L 21/336

(52) U.S. Cl. 438/268

(57) ABSTRACT

FinFET diode structures and methods are provided for building the FinFET diode structures. A FinFET diode structure is created by implanting a diffusion Fin on a first side with a P+ dopant and on a second side with a N+ dopant providing a P+N+ diode structure.

### FIELD OF THE INVENTION

The present invention relates generally to the data processing field, and more particularly, relates to Fin field effect transistor (FET) diode or FinFET diode structures and methods for building the FinFET diode structures.

### DESCRIPTION OF THE RELATED ART

A diode can be built in a FinFET silicon-on-insulator (SOI) technology in a fashion generally identical to those built in today's planar SOI technologies or bulk CMOS technologies. The diode can simply be built using planar devices built wide enough to align a block diffusion (BN/BP) over the gate region as they are built today without the use of any Fin structures. However, these diodes would be P+ diffusion to N-body diodes with high series resistance. This characteristic limits their effectiveness and increases their size.

FIG. 1 illustrates a conventional diode design. In SOI technologies, polysilicon-bounded ring diodes are used. In this technology, only one type of diode design is supported. The diode is formed between a P+ source/drain diffusion region and an N-body region. These diodes are P+ diffusion to N-body diodes with high series resistance, and have limited effectiveness and increased size. A cross sectional view of the prior art diode is shown in FIG. 1.

A need exists for a diode structure having an improved diode characteristic and it is desirable to provide such a diode structure that has a physically smaller size.

### SUMMARY OF THE INVENTION

Principal aspects of the present invention are to provide improved FinFET diode structures and methods for building the FinFET diode structures. Other important objects of the present invention are to provide such FinFET diode structures and methods for building the FinFET diode structures substantially without negative effect and that overcome many of the disadvantages of prior art arrangements.

In brief, FinFET diode structures and methods are provided for building the FinFET diode structures. A FinFET diode structure is created by implanting a diffusion Fin on a first side with a P+ dopant and on a second side with a N+ dopant providing a P+N+ diode structure.

In accordance with features of the invention, angled implants are performed for implanting the respective N+ and P+ dopants. The diffusion Fin is formed of a semiconductor material, such as Silicon including a single crystalline Silicon. The Fin width is sized such that the resulting PN junction diode has a reasonably abrupt P+/N+ junction and enhanced diode characteristics. The Fin width has a selected width, for example, in a range from 25 nanometers (nm) to 500 nm.

### BRIEF DESCRIPTION OF THE DRAWINGS

The present invention together with the above and other objects and advantages may best be understood from the following detailed description of the preferred embodiments of the invention illustrated in the drawings, wherein:

FIG. 1 is cross sectional view illustrating a conventional diode;

FIG. 2 is a perspective view illustrating an exemplary FinFET diode structure in accordance with the preferred embodiment;

FIG. 3 is a perspective view illustrating a second exemplary FinFET diode structure with solid arrows indicating P+ angled ion implants and dotted arrows indicating N+ angled ion implants in accordance with the preferred embodiment;

FIG. 4 is an elevational view illustrating exemplary mask shapes for the FinFET diode structure of FIG. 3 in accordance with the preferred embodiment;

FIG. 5 is a perspective view illustrating another exemplary FinFET diode structure in accordance with the preferred embodiment;

FIG. 6 is an elevational view illustrating an exemplary mask shape for the FinFET diode structure of FIG. 5 in accordance with the preferred embodiment; and

FIG. 7 is a perspective view illustrating a further exemplary serpentine FinFET diode structure in accordance with the preferred embodiment.

### DETAILED DESCRIPTION OF THE PREFERRED EMBODIMENTS

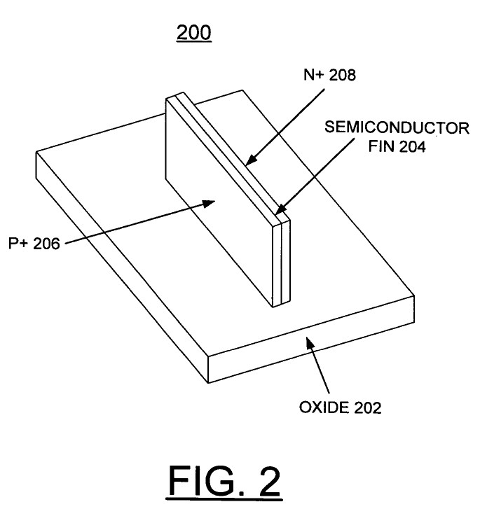

Having reference now to the drawings, in FIG. 2 there is shown an exemplary FinFET diode structure in accordance with the preferred embodiment generally designated by the reference character 200. The exemplary FinFET diode structure 200 includes a non-conductive substrate or oxide 202 supporting a diffusion Fin or FinFET semiconductor Fin 204. It should be understood that the invention is applicable to various semiconductor technologies, for example, silicon on insulator (SOI), complementary metal oxide semiconductor (CMOS), BiCMOS, bipolar, and silicon germanium (SiGe), as long as the FinFET semiconductor Fin 204 is electrically isolated from other such fins and the substrate.

In accordance with features of the preferred embodiment, a diode structure, such as the exemplary FinFET diode structure 200 is created by implanting the FinFET semiconductor Fin 204 on one side with P+ dopant 206 and on the other side with N+ dopant 208. This results in the P+N+ diode structure 200 shown in FIG. 2.

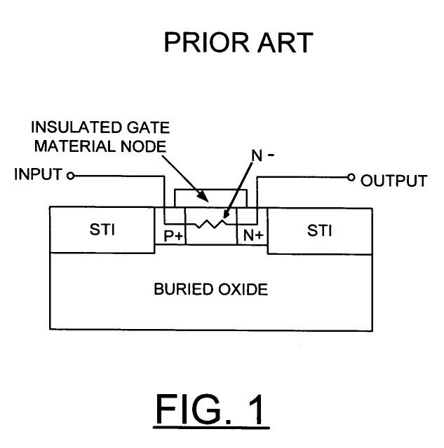

The semiconductor Fin 204 is formed in Silicon, such as single crystalline Si, or other semiconducting material. The Fin width is sized such that the resulting PN junction diode has a reasonably abrupt P+/N+ junction and the best diode characteristics possible. The Fin width is a selected width in a range, for example, from 25 nanometers (nm) to 500 nm dependent on the fin shape definition limitation and implantation energy of the N and P node. Note the elimination/reduction of the N-region as compared to the conventional diode shown FIG. 1.

In normal FinFET processing two angled implants of the same dopant type are performed to create either N+ or P+ drain and source diffusions. These implants are first aimed at one side of the Fin and then the other. Formation of the FinFET diode structure 200 of the preferred embodiment is an extension of this basic process.

This exemplary FinFET diode structure 200 has a more ideal diode characteristic and is physically smaller than a conventional diode built using the conventional SOI technique.

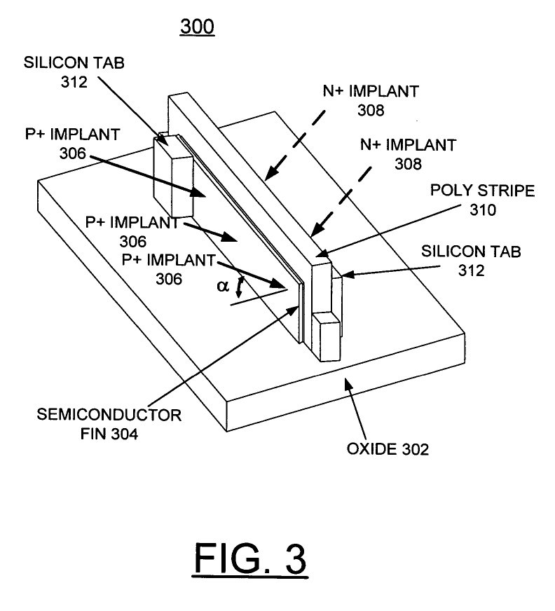

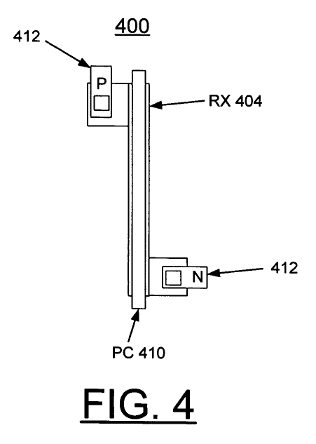

Referring also to FIGS. 3 and 4, there are shown another exemplary resulting FinFET diode structure in FIG. 3 in accordance with the preferred embodiment generally designated by the reference character 300 and exemplary sample mask shapes generally designated by the reference character 400 in FIG. 4 for the FinFET diode structure 300 in accordance with the preferred embodiment.

In accordance with features of the preferred embodiment, angled ion implants used to create the P+/N+ diode structure out of a semiconductor fin 304 are indicated with a plurality of solid arrows labeled P+ IMPLANT 306 and a plurality of dotted arrows labeled N+ IMPLANT 308. Diffusion fin 304 corresponds to a shape labeled RX 404 in FIG. 4. An insulated gate material node 310, such as, a polysilicon material or poly stripe 310 running lengthwise down the top and ends of the semiconductor Fin structure 304, acts as a stop during silicide formation. The poly stripe 310 corresponds to a shape labeled PC 410 in FIG. 4. Traditional silicide formation otherwise would short the two sides of the FinFET diode structure 300 together without the gate material 310. A pair of silicon tabs 312 on the ends of the FinFET diode structure 300 provides landing sites for a pair of contact connections or shapes 412 in FIG. 4 to the diode's anode and cathode.

FIGS. 3 and 4 assume the FinFET diode structure 300 is formed using unique mask shapes 400 and process steps. The unique mask shapes 400 is only used to isolate the area in which the FinFET diode structures 300 are being built from areas where conventional transistors are formed. A basic feature of the preferred embodiment is to mask off the rest of a chip and open the area where just diodes of the FinFET diode structure 300 exist and perform at least one unique implant, for example, implant from one angle α on one side of the Fin structure 304 to either form or overdope a drain/source implant and thus create one node, either the N+ or P+ ion implants, of the diodes. This FinFET diode structure 300 requires that all diode structures be formed in one direction only, that is straight diode structures as shown and all such diode structures parallel to each other. The other node of the diode may be formed by either conventional drain or source implants, allowing either P-type device drain/source implants or N-type device drain source implants, or by using the same unique mask opening and implanting the alternate diode node as well.

Using one or more unique implants P+ IMPLANT 306, N+ IMPLANT 308, allows an abrupt junction to be formed in the Fin 304 eliminating the only lightly doped intrinsic region normally present between the two nodes in conventional diode structures with polysilicon gates isolating the two nodes. An abrupt junction of FinFET diode structure 300 provides greatly reduced series resistance and much more desirable ideal diode characteristics. FinFET diode structure 300 of the preferred embodiment is useful for both output driver protect structures and thermal diode temperature sensing application requirements.

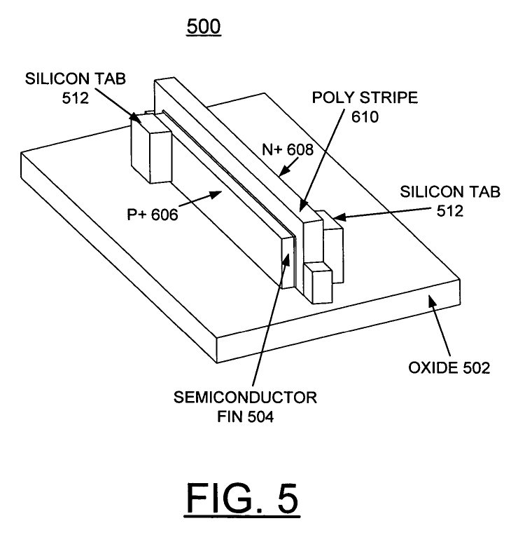

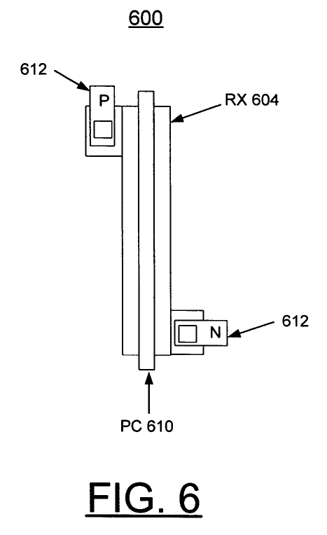

Referring also to FIGS. 5 and 6, there are shown another exemplary resulting FinFET diode structure in FIG. 5 in accordance with a preferred embodiment generally designated by the reference character 500 and exemplary sample mask shapes generally designated by the reference character 600 in FIG. 6 for the FinFET diode structure 500 in accordance with the preferred embodiment.

In accordance with features of the preferred embodiment, the FinFET diode structure 500 is created using standard mask and processing steps. When using standard mask and processing steps, the semiconductor fin 504 must be wider to accommodate alignment of the N+ implant blocking design level and the P+ implant blocking design level. The N+ implant blocking design level and the P+ implant blocking design level are referred to as the BP and BN masks. Wider diffusion fin 504 corresponds to a shape labeled RX 604 in FIG. 6. The resulting diode characteristic of the FinFET diode structure 500 is compromised; however, the device is still better than a conventional planar SOI diode structure due to the potentially larger diode surface area and larger lightly doped body region cross-section. When the FinFET diode structure 500 is constructed using standard mask and processing steps, then any shape diode structure can be implemented.

FinFET diode structure 500 similarly includes a poly stripe 510 running lengthwise down the top and ends of the FinFET diode structure 500, that acts as a stop during silicide formation. The poly stripe 510 corresponds to a shape labeled PC 610 in FIG. 6. A pair of silicon tabs 512 on the ends of the FinFET diode structure 500 similarly provides landing sites for a pair of contact connections or shapes 612 in FIG. 6 to the diode's anode and cathode.

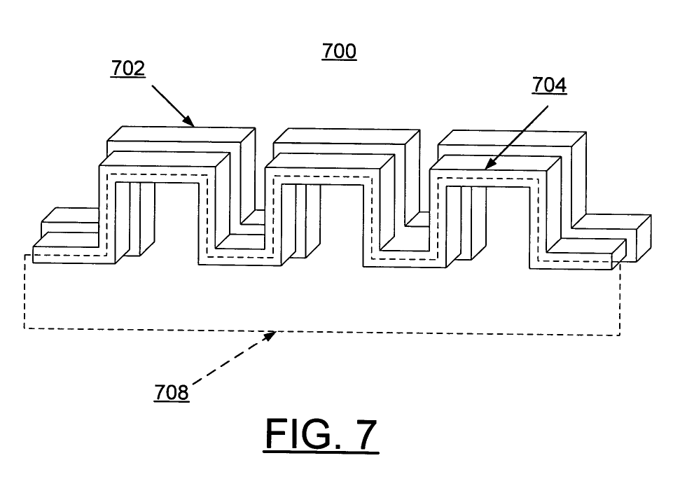

Referring to FIG. 7, there is shown an exemplary serpentine FinFET diode structure in accordance with a preferred embodiment generally designated by the reference character 700. Serpentine FinFET diode structure 700 includes a silicon diffusion area or Fin generally designated by the reference character 702, a gate generally designated by the reference character 704 with a BN/BP mask generally designated by the reference character 708 shown in dotted line. Serpentine FinFET diode structure 700 has the advantages of not requiring any unique mask layers or process steps for the construction of the diode. These diode characteristics per unit length of device are likely to be better than what could be produced in a planar structure but not nearly as good as the FinFET diode structure 300 with unique mask shapes 400 and processing steps including at least one new implant. Serpentine FinFET diode structure 700 however will have a lightly doped, intrinsic region between the two nodes of the diode and therefore would have a higher series resistance making it less desirable from an electrical point of view to what has been described above in accordance with the preferred embodiment.

In brief, the Fin adaptation of the preferred embodiment is an improvement over the prior art planar structure but the greatest improvement can be realized with the new mask and unique implant or implants.

While the present invention has been described with reference to the details of the embodiments of the invention shown in the drawing, these details are not intended to limit the scope of the invention as claimed in the appended claims.

1-9. (canceled)

10. A method for building FinFET diode structures comprising the steps of:
forming a vertically oriented diffusion Fin having a first side and a second side;
implanting the diffusion Fin on a first side with a P+ dopant;
implanting the diffusion Fin on a second side with a N+ dopant to provide a P+N+ diode structure; and
each of said implanting steps includes providing an angled implant to form an abrupt junction in said vertically oriented diffusion Fin.

11. A method for building FinFET diode structures as recited in claim 10 wherein the step of forming said vertically oriented diffusion Fin includes forming a vertically oriented diffusion Fin having a selected width.

12. A method for building FinFET diode structures as recited in claim 11 wherein the selected width of said vertically oriented diffusion Fin is a selected width in a range between 25 nanometers (nm) to 500 nm.

13. A method for building FinFET diode structures as recited in claim 10 wherein the step of forming said vertically oriented diffusion Fin includes forming said vertically oriented diffusion Fin of a semiconductor material.

14. A method for building FinFET diode structures as recited in claim 10 wherein the step of forming said vertically oriented diffusion Fin includes forming said vertically oriented diffusion Fin of Silicon.

15. A method for building FinFET diode structures as recited in claim 10 wherein the step of forming said vertically oriented diffusion Fin includes forming said vertically oriented diffusion Fin of a single crystalline Silicon.

16-17. (canceled)

18. A method for building FinFET diode structures as recited in claim 10 includes forming a stripe of polysilicon material extending lengthwise along a top and opposed ends of said diffusion Fin; said polysilicon material acting as a stop during silicide formation.

19. A method for building FinFET diode structures as recited in claim 10 includes forming a pair of silicon tabs on the first side and the second side of said diffusion Fin for providing landing sites for a pair of contact connections.
